(19) United States
(12) Patent Application Publication
(10) Pub. No.: US 2025/0138090 A1
(43) Pub. Date: May 1, 2025

(54) Battery System Capable of Pack Relay Diagnosis and Vehicle Comprising the Same

(71) Applicant: LG Energy Solution, Ltd., Seoul (KR)

(72) Inventor: Jesung Ryu, Daejeon (KR)

(73) Assignee: LG Energy Solution, Ltd., Seoul (KR)

(21) Appl. No.: 18/836,820

(22) PCT Filed: Mar. 14, 2023
(86) PCT No.: PCT/KR2023/003426

§ 371 Date: Aug. 8, 2024

(30) Foreign Application Priority Data
Mar. 16, 2022 (KR) 10-2022-0032752

(51) Int. Cl. G01R 31/327; B60L 58/18; G01R 31/00; G01R 31/54; H01M 10/42; H01M 50/204; H02J 7/00; H02J 7/34

(52) U.S. Cl. CPC G01R 31/3278; B60L 58/18; G01R 31/005; G01R 31/54; H01M 10/4264; H01M 50/204; H02J 7/0063; H02J 7/345; H01M 2010/4271; H01M 2220/20

(57) ABSTRACT

A battery system may include a plurality of battery packs, a plurality of first relays, each first relay of the plurality of first relays connected between a positive electrode of each respective battery pack of the plurality of battery packs and each respective first node of a plurality of first nodes for each of the plurality of battery packs, a plurality of second relays connected between a negative electrode of the respective battery pack and each respective second node of a plurality of second nodes for each of the plurality of battery packs, a capacitor having both ends connected between a first wiring connected to the plurality of first nodes and a second wiring connected to the plurality of second nodes, a resistor and a switch connected in series between the first wiring and the second wiring, and a plurality of pack battery management systems (BMS).

### CROSS-REFERENCE TO RELATED APPLICATION

The present application is a national phase entry under 35 U.S.C. § 371 of International Application No. PCT/KR2023/003426 filed Mar. 14, 2023, which claims priority from Korean Patent Application No. 10-2022-0032752 filed in the Korean Intellectual Property Office on Mar. 16, 2022, the entire contents of which are incorporated herein by reference.

### TECHNICAL FIELD

The present disclosure relates to a battery system capable of diagnosing a pack relay and a vehicle including the same.

### BACKGROUND ART

A battery system may include a plurality of battery packs connected in parallel to a junction box. Power may be supplied to a vehicle from a plurality of battery packs through the junction box. As the number of battery packs connected in parallel increases, the battery system may supply more power. Each of the plurality of battery packs includes a pack relay connected to the junction box and a pack battery management system (hereinafter referred to as a pack BMS) that controls an operation of the pack relay. When the relays of each of the plurality of battery packs are closed and the relay of the junction box is closed, power may be supplied to the vehicle from each of the battery packs.

After the pack BMS wakes up, the pack BMS controls the pack relay to be closed. Thereafter, the pack BMS determines whether the pack relay is normally closed. Hereinafter, an operation of determining whether the pack relay is normally closed is referred to as pack relay diagnosis.

Specifically, the pack BMS measures voltages at both ends of the pack relay, respectively, and compares the voltages at both ends thereof, respectively, to diagnose the pack relay. However, since one end of the plurality of pack relays is connected to the junction box through one link bus bar, the voltage of one end of the pack relay that is not closed among the plurality of pack relays may be similar to that of the battery pack. According to the conventional methods for solving such a problem, the time required for diagnosing the pack relay is considerable.

Even when performing the pack relay diagnosis sequentially for the plurality of pack relays one by one, the considerable time is required.

### SUMMARY

### Technical Problem

The present disclosure attempts to provide a battery system capable of diagnosing a pack relay capable of reducing a time required for diagnosing a plurality of pack relays, and a vehicle including the same.

### Technical Solution

According to an aspect of the present disclosure, a battery system may include a plurality of battery packs, a plurality of first relays, each first relay of the plurality of first relays connected between a positive electrode of each respective battery pack of the plurality of battery packs and each respective first node of a plurality of first nodes for each of the plurality of battery packs, a plurality of second relays connected between a negative electrode of the respective battery pack and each respective second node of a plurality of second nodes for each of the plurality of battery packs, a capacitor having both ends connected between a first wiring connected to the plurality of first nodes and a second wiring connected to the plurality of second nodes, a resistor and a switch connected in series between the first wiring and the second wiring, and a plurality of pack battery management systems (BMSs) configured to control the plurality of first relays and the plurality of second relays to be closed and, while the plurality of first relays and the plurality of second relays are closed, determine the plurality of first relays and the plurality of second relays are normal when a current flowing from the plurality of battery packs to the capacitor is detected.

According to another aspect of the present disclosure, a vehicle may include a battery system and a power device receiving power from the battery system or charging the battery system. The battery system may include a plurality of battery packs, a plurality of first relays, each first relay of the plurality of first relays connected between a positive electrode of each respective battery pack of the plurality of battery packs and each respective first node of a plurality of first nodes for each of the plurality of battery packs, a plurality of second relays connected between a negative electrode of the corresponding battery pack and each respective second node of a plurality of second nodes for each of the plurality of battery packs, a capacitor having both ends connected between a first wiring connected to the plurality of first nodes and a second wiring connected to the plurality of second nodes, a resistor and a switch connected in series between the first wiring and the second wiring, and, a plurality of pack battery management systems (BMSs) configured to control the plurality of first relays and the plurality of second relays to be closed and, while the plurality of first relays and the plurat of second relays are closed, determine the plurality of first relays and the plurality of second relays are normal when a current flowing from the plurality of battery packs to the capacitor is detected.

The battery system may further include a plurality of current sensors, each current sensor of the plurality of current sensors configured to detect a current flowing to each battery pack of the plurality of battery packs.

Each pack BMS of the plurality of pack BMSs may be configured to receive a current sensing signal from each respective current sensor, and when the received current sensing signal indicates a zero current, diagnose that at least one of the first relay connected to the positive electrode of the respective battery pack and second relay connected to the negative electrode of the respective battery pack is in a stuck open state.

The battery system may further include a main control integrated circuit (IC) configured to discharge the capacitor by turning on the switch for a predetermined discharging period when an operation of the battery system ends.

The battery system may further include a first main relay connected between a first input terminal of a power device connected to the battery system and positive electrodes of the plurality of battery packs; and a second main relay connected between a second input terminal of the power device and negative electrodes of the plurality of battery packs. The capacitor, the resistor, and the switch may be positioned between the first wiring connecting the firs main relay to the positive electrodes of the plurality of battery packs and the second wiring connecting the second main relay to the negative electrodes of the plurality of battery packs.

The plurality of pack BMSs may be configured to control the first main relay and the second main relay to be in an open state during a period in which the plurality of pack BMSs determine whether the plurality of first relays and the plurality of second relays are normal.

The battery system may further include a connection switch connected between the first wiring and the capacitor or between the second wiring and the capacitor.

### Advantageous Effects

According to the present disclosure, it is possible to provide a battery system capable of diagnosing a pack relay capable of reducing a time required for diagnosing a plurality of pack relays, and a vehicle including the same

### BRIEF DESCRIPTION OF THE DRAWINGS

FIG. 1 is a diagram schematically illustrating a battery system and a vehicle including the battery system according to an embodiment.

FIG. 2 is a flowchart illustrating a method of diagnosing a pack relay according to an exemplary embodiment.

FIG. 3 is a diagram schematically illustrating a battery system and a vehicle including the battery system according to another exemplary embodiment.

### DETAILED DESCRIPTION

Hereafter, embodiments of the present disclosure will be described in detail with reference to the accompanying drawings and the same or similar components are given the same reference numerals and are not repeatedly described. The suffix “module” and/or “unit” for components used in the following description is given or mixed in consideration of only the ease of writing of the specification, and therefore, do not have meanings or roles that distinguish from each other in themselves. Further, when it is decided that a detailed description for the known art related to the present disclosure may obscure the gist of the present disclosure, the detailed description will be omitted. Further, it should be understood that the accompanying drawings are provided only in order to allow exemplary embodiments of the present disclosure to be easily understood, and the spirit of the present disclosure is not limited by the accompanying drawings, but includes all the modifications, equivalents, and substitutions included in the spirit and the scope of the present disclosure.

Terms including an ordinal number such as first, second, etc., may be used to describe various components, but the components are not limited to these terms. The terms are used only to distinguish one component from another component.

Further, in the present specification, it is to be understood that when one component is referred to as being “connected to” or “coupled to” another component, it may be connected or coupled directly to another component or be connected to another component with the other component interposed therebetween. On the other hand, it should be understood that when one element is referred to as being “connected directly to” or “coupled directly to” another element, it may be connected to or coupled to another element without the other element interposed therebetween.

It will be further understood that terms “include” or “have” used in the present specification specify the presence of features, numerals, steps, operations, components, parts mentioned in the present specification, or combinations thereof, but do not preclude the presence or addition of one or more other features, numerals, steps, operations, components, parts, or combinations thereof.

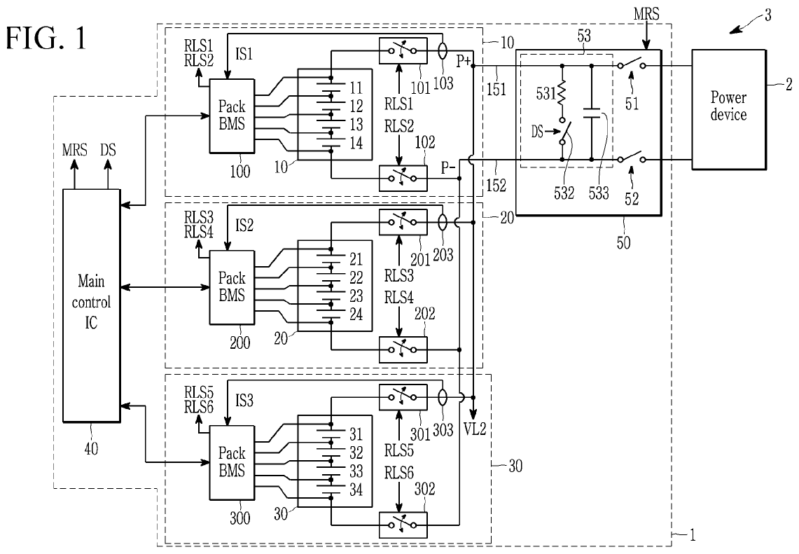

FIG. 1 is a diagram schematically illustrating a battery system and a vehicle including the battery system according to an embodiment.

A vehicle 3 includes a battery system 1 and a power device 2. In an exemplary embodiment, a vehicle is taken as an example of a device to which the battery system 1 is applied, but the present disclosure is not limited thereto. The vehicle 3 includes, for example, a hybrid vehicle or the like that is driven only by a motor without an internal combustion engine or includes both an internal combustion engine and a motor.

The battery system 1 includes a plurality of battery packs 10 to 30, a main control integrated circuit (IC) 40, and a junction device 50. Although the number of battery packs is illustrated in FIG. 1 as three, the present disclosure is not limited thereto and the battery system 1 may include four or more battery packs. In addition, although the plurality of battery packs 10 to 30 are illustrated in parallel in FIG. 1, two or more battery packs may be connected in series, and a plurality of battery packs connected in series may be connected in parallel.

The power device 2 may be a load receiving power from the battery system 1 or a charger for charging the battery system 1. For example, the power device 2 may include at least one of an inverter, a DC-DC converter, a motor, an electronic control circuit, an on board charger (OBC), and a fast charger of the vehicle 3. The power device 2 includes two input terminals IN1 and IN2.

The plurality of battery packs 10 to 30 are connected in parallel to each other, and both ends of the plurality of battery packs 10 to 30 are each connected to the junction device 50 through wirings 151 and 152, respectively.

The junction device 50 includes a first main relay 51 connected between the wiring 151 and an input terminal IN1 of the power device 2, and a second main relay 52 connected between the wiring 152 and an input terminal IN2 of the power device 2. The first and second main relays 51 and 52 may control the connection between the plurality of battery packs 10 to 30 and the power device 2, and the main control IC 40 may control operations of the first and second main relays 51 and 52 to generate a relay control signal (MRS) and transmit the generated relay control signal to the junction device 50.

The junction device 50 may control the opening and closing of the first and second main relays 51 and 52 according to the relay control signal MRS. Although the junction device 50 is illustrated as including a pair of main relays in FIG. 1, the number of main relay pairs may be determined according to the number of configurations of the power device 2.

In an exemplary embodiment, the junction device 50 further includes a diagnostic circuit 53. The diagnostic circuit 53 includes a resistor 531, a switch 532, and a capacitor 533.

One end of the resistor 531 is connected to the wiring 151, the other end of the resistor 531 is connected to one end of the switch 532, and the other end of the switch 532 is connected to the wiring 152. One end of the capacitor 533 is connected to the wiring 151, and the other end of the capacitor 533 is connected to the wiring 152. The switch 532 may perform a switching operation according to a discharge signal DS transmitted from the main control device 40. In the junction device 50, the diagnostic circuit 53 needs to be connected between the first main relay 51 and the second main relay 52 and the plurality of relays 101, 102, 201, 202, 301 and 302. The main control IC 40 may control the first and second main relays 51 and 52 to be open during a pack relay diagnosis period for the plurality of relays 101, 102, 201, 202, 301, and 302.

Unlike what is illustrated in FIG. 1, the diagnostic circuit 53 may be implemented as a separate configuration separated from the junction device 50. Even in this case, the diagnostic circuit 53 needs to be connected between the junction device 50 and the plurality of relays 101, 102, 201, 202, 301, and 302.

The plurality of battery packs 10 to 30 include a plurality of battery cells 11 to 14, 21 to 24, and 31 to 34, the plurality of pack battery management systems 100, 200, and 300, the plurality of relays 101, 102, 201, 202, 301, and 302, and a plurality of current sensors 103, 203, 303. Hereinafter, the pack battery management system is referred to as a pack battery management system (pack BMS). In FIG. 1, each of the plurality of battery packs 10 to 30 is illustrated as including the four battery cells 11 to 14, 21 to 24, and 31 to 34, but this is an example and the present disclosure is not limited thereto. In addition, each of the plurality of battery packs 10 to 30 is illustrated as including two relays, but this is an example, and the number of relays may be at least one.

Each of the plurality of pack BMSs 100, 200, and 300 is connected to a plurality of corresponding battery cells 11 to 14, 21 to 24, and 31 to 34, and measures cell voltages of the plurality of battery cells 11 to 14, 21 to 24, and 31 to 34. Each of the plurality of pack BMSs 100, 200, and 300 may acquire a voltage (hereinafter, battery pack voltage), a current (hereinafter, battery pack current), and a temperature (hereinafter, temperature of battery pack) of each of the corresponding battery packs 10, 20, and 30. Each of the plurality of pack BMSs 100, 200 and 300 may control the charging and discharging of the battery packs 10 to 30 based on the cell voltages of the plurality of corresponding battery cells 11 to 14, 21 to 24, and 31 to 34, the battery pack current, and the like, and control and perform a cell balancing operation for the plurality of battery cells 11 to 14, 21 to 24, and 31 to 34.

The plurality of pack BMSs 100, 200, and 300 open and close each of the plurality of relays 101, 102, 201, 202, 301, and 302 to control the charging and discharging of the plurality of battery packs 10 to 30. The relay 101 is connected between a positive electrode of the battery pack 10 and a node P+, and the relay 102 is connected between an negative electrode of the battery pack 10 and a node P−. The relay 201 is connected between the positive electrode of the battery pack 20 and the node P+, and the relay 202 is connected between the negative electrode of the battery pack 20 and the node P−. The relay 301 is connected between the positive electrode of the battery pack 30 and the node P+, and the relay 302 is connected between the negative electrode of the battery pack 30 and the node P−.

Each of the plurality of pack BMSs 100, 200, and 300 may control the opening and closing of the corresponding two relays 101/102, 201/202, and 301/302 to generate two drive signals RLS1/RLS2, RLS3/RLS4, and RLS5/RLS6 and supply the generated drive signals RLS1/RLS2, RLS3/RLS4, and RLS5/RLS6 to the corresponding two relays 101/102, 201/202, and 301/302.

The main control IC 40 may receive the information on the cell voltages of the plurality of battery cells 11-15, 21-25, and 31-35 from the plurality of pack BMSs 100, 200, and 300, the battery pack voltage for the plurality of battery packs 10, 20, and 30, the battery pack current, and the battery pack temperature, and the like. The main control IC 40 may supply a power control signal to the plurality of pack BMSs 100, 200, and 300 to supply power to the outside, or may supply a charging control signal to the plurality of pack BMSs 100, 200, and 300 to charge the plurality of battery packs 10, 20, and 30. In addition, the main control IC 40 may perform control necessary for the operation of the battery system 1 and start and perform control by performing a protection operation when an abnormal state of the battery system 1 is detected.

Each of the plurality of current sensors 103, 203, and 303 may measure the battery pack current to transmit signals (hereinafter, current detection signals) IS1, IS2, and IS3 instructing the measured current to each of the plurality of pack BMSs 100, 200, and 300.

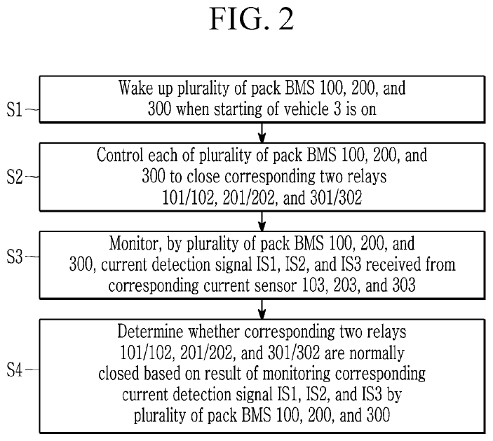

FIG. 2 is a flowchart illustrating a method of diagnosing a pack relay according to an exemplary embodiment.

When the starting of the vehicle 3 is on, the plurality of pack BMSs 100, 200, and 300 wake up (S1). After waking up, the plurality of pack BMSs 100, 200, and 300 may determine whether the plurality of relays 101/102, 201/202, and 301/302 are normally closed.

After waking up, each of the plurality of pack BMSs 100, 200, and 300 controls to close the corresponding two relays 101/102, 201/202, and 301/302 (S2).

Each of the plurality of pack BMSs 100, 200, and 300 may monitor the current detection signals IS1, IS2, and IS3 received from the corresponding current sensors 103, 203, and 303 after controlling the corresponding two relays 101/102, 201/202, and 301/302 to be closed (S3).

Each of the plurality of pack BMSs 100, 200, and 300 may determine whether the corresponding two relays 101/102, 201/202, and 301/302 are normally closed based on the results of monitoring the corresponding current detection signals IS1, IS2, and IS3 (S4). The first and second main relays 51 and 52 of the junction device 50 are in an open state during a period in which the states of the two relays 101/102, 201/202, and 301/302 corresponding to each of the plurality of pack BMSs 100, 200, and 300 are diagnosed.

Immediately after waking up, when the corresponding two relays 101/102, 201/202, and 301/302 are normally closed, a current flows from the corresponding battery packs 10, 20, and 30 to a capacitor 533, and the corresponding current sensors 103, 203, and 303 may detect the current.

For example, the two relays 101 and 102 receive relay control signals RLS1 and RLS2 instructing closing from the pack BMS 100. When two relays 101 and 102 are normally closed, a current flows from the battery pack 10 to the capacitor 533, and the current sensor 103 detects a current flowing to the capacitor 533 and generates the current detection signal IS1. The current detection signal IS1 is transmitted to the pack BMS 100, and the pack BMS 100 determines that two relays 101 and 102 are normally closed based on the current sensing signal IS1. When at least one of the two relays 101 and 102 is in a stuck open state, at least one of the two relays 101 and 102 is not closed despite the closing control. Then, no current flows from the battery pack 10 to the capacitor 533. The pack BMS 100 may determine that at least one of the two relays 101 and 102 is in the stuck open state when the current detection signal IS1 received from the current sensor 103 indicates zero current.

The two relays 201 and 202 receive the relay control signals RLS3 and RLS4 instructing closing from the pack BMS 200. When two relays 201 and 202 are normally closed, a current flows from the battery pack 20 to the capacitor 533, and the current sensor 203 detects the current flowing to the capacitor 533 and generates the current detection signal IS2. The current detection signal IS2 is transmitted to the pack BMS 200, and the pack BMS 200 determines that two relays 201 and 202 are normally closed based on the current sensing signal IS2. When at least one of the two relays 201 and 202 is in the stuck open state, at least one of the two relays 201 and 202 is not closed despite the closing control. Then, no current flows from the battery pack 20 to the capacitor 533. The pack BMS 200 may determine that at least one of the two relays 201 and 202 is in the stuck open state when the current detection signal IS2 received from the current sensor 203 indicates zero current.

The two relays 301 and 302 receive the relay control signals RLS3 and RLS4 instructing closing from the pack BMS 300. When two relays 301 and 302 are normally closed, a current flows from the battery pack 30 to the capacitor 533, and the current sensor 303 detects a current flowing to the capacitor 533 and generates the current detection signal IS3. The current detection signal IS3 is transmitted to the pack BMS 300, and the pack BMS 300 determines that two relays 301 and 302 are normally closed based on the current sensing signal IS3. When at least one of the two relays 301 and 302 is in the stuck open state, at least one of the two relays 301 and 302 is not closed despite the closing control. Then, no current flows from the battery pack 30 to the capacitor 533. The pack BMS 300 may determine that at least one of the two relays 303 and 301 is in the stuck open state when the current detection signal IS3 received from the current sensor 302 indicates zero current.

The plurality of pack BMSs 100, 200, and 300 may wake up simultaneously when the operation of the battery system 1 starts. When the operation of the battery system 1 ends, the main control IC 40 generates a discharge signal DS to turn on the switch 532 for a predetermined discharge period. Then, the capacitor 533 can be discharged through the resistor 531 and the switch 532. The predetermined discharge period may be set to a time sufficient for the capacitor 533 to be discharged to zero voltage. The operation of the battery system 1 may start when the starting of the vehicle 3 is on, and may end when the starting of the vehicle 3 is off. The operation of the battery system 1 may include a discharging operation for supplying power and a charging operation for receiving power.

Each of the plurality of pack BMSs 100, 200, and 300 may notify the main control IC 40 that the diagnosis result of the corresponding two relays is in the stuck open state. The main control IC 40 may keep the first and second relays 51 and 52 open when there is a stuck-open relay among the plurality of relays 101, 102, 201, 202, 301, and 302. The main control IC 40 controls the first and second relays 51 and 52 of the junction device 50 to be closed when all of the plurality of relays 101, 102, 201, 202, 301, and 302 are in a normal state. The main control IC 40 may generate an off-level relay control signal MRS and transmit the generated off-level relay control signal to the junction device 50 in order to control the first and second main relays 51 and 52 to be in the open state. The main control IC 40 may generate an on-level relay control signal MRS and transmit the generated on-level relay control signal to the junction device 50 in order to control the first and second main relays 51 and 52 to be in the closed state.

In FIG. 1, it is shown that the capacitor 533 is directly connected between the wiring 151 and the wiring 153, but the present disclosure is not limited thereto.

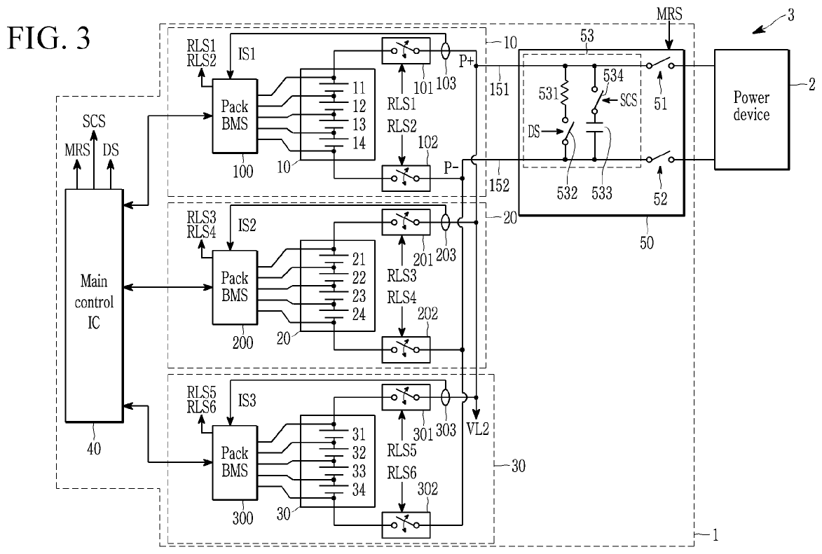

FIG. 3 is a diagram schematically illustrating a battery system and a vehicle including the battery system according to another exemplary embodiment.

Among the components illustrated in FIG. 3, descriptions of components identical to those illustrated in FIG. 1 will be omitted. As illustrated in FIG. 3, the diagnostic circuit 53 may further include a connection switch 534 connected between one of the wiring 151 and wiring 152 and the capacitor 533. For example, a connection switch 534 may be connected between the capacitor 533 and the wiring 151. One end of connection switch 534 is connected to the wiring 151, an end of the capacitor 533 is connected to the other end of the connection switch 534, and the other end of the capacitor 533 is connected to the wiring 152. The connection switch 534 may perform a switching operation according to a switch control signal (SCS).

The main control IC 40 may control the connection switch 534 to be in an on state during the diagnosis period for the two relays corresponding to the plurality of pack BMSs 100, 200, and 300, respectively, and when the diagnosis period ends, control the connection switch 534 to be in an off state. To this end, the main control IC 40 may further generate the switch control signal (SCS). The main control IC 40 may generate the on-level switch control signal (SCS) during the diagnosis period and generate the off-level switch control signal (SCS) when the diagnosis period ends. After the diagnosis period ends, the connection switch 534 is turned off, and the capacitor 533 may not be involved in the operation of the battery system 1 other than the diagnosis operation.

Although the embodiments of the present disclosure have been described in detail above, the scope of the present disclosure is not limited thereto, and various modifications and improvements by those of ordinary skill in the field to which the present disclosure pertains belong to the scope of the present disclosure.

1. A battery system, comprising:
a plurality of battery packs;
a plurality of first relays, each first relay of the plurality of first relays connected between a positive electrode of each respective battery pack of the plurality of battery packs and each respective first node of a plurality of first nodes for each of the plurality of battery packs;
a plurality of second relays connected between a negative electrode of the respective battery pack and each respective second node of a plurality of second nodes for each of the plurality of battery packs;
a capacitor having both ends connected between a first wiring connected to the plurality of first nodes and a second wiring connected to the plurality of second nodes;
a resistor and a switch connected in series between the first wiring and the second wiring; and
a plurality of pack battery management systems (BMSs) configured to control the plurality of first relays and the plurality of second relays to be closed and, while the plurality of first relays and the plurality of second relays are closed, determine the plurality of first relays and the plurality of second relays are normal when a current flowing from the plurality of battery packs to the capacitor is detected.

2. The battery system of claim 1, further comprising:
a plurality of current sensors, each current sensor of the plurality of current sensors configured to detect a current flowing to each battery pack of the plurality of battery packs.

3. The battery system of claim 2, wherein:
each pack BMS of the plurality of pack BMSs is configured to:
receive a current sensing signal from each respective current sensor, and when the received current sensing signal indicates a zero current, diagnose that at least one of the first relay connected to the positive electrode of the respective battery pack and second relay connected to the negative electrode of the respective battery pack is in a stuck open state.

4. The battery system of claim 1, further comprising:
a main control integrated circuit (IC) configured to discharge the capacitor by turning on the switch for a predetermined discharging period when an operation of the battery system ends.

5. The battery system of claim 1, further comprising:
a first main relay connected between a first input terminal of a power device connected to the battery system and positive electrodes of the plurality of battery packs; and
a second main relay connected between a second input terminal of the power device and negative electrodes of the plurality of battery packs;
wherein the capacitor, the resistor, and the switch
are positioned between the first wiring connecting the first main relay to the positive electrodes of the plurality of battery packs and the second wiring connecting the second main relay to the negative electrodes of the plurality of battery packs.

6. The batter system of claim 5, wherein:
the plurality of pack BMSs are configured to control the first main relay and the second main relay
to be in an open state during a period in which the plurality of pack BMSs determine whether the plurality of first relays and the plurality of second relays are normal.

7. The battery system of claim 1, further comprising:
a connection switch connected between the first wiring and the capacitor or between the second wiring and the capacitor.

8. A vehicle, comprising:
a battery system; and
a power device receiving power from the battery system or charging the battery system,
wherein the battery system includes:
a plurality of battery packs;
a plurality of first relays, each first relay of the plurality of first relays connected between a positive electrode of each respective battery pack of the plurality of battery packs and each respective first node of a plurality of first nodes for each of the plurality of battery packs;
a plurality of second relays connected between a negative electrode of the corresponding battery pack and each respective second node of a plurality of second nodes for each of the plurality of battery packs;
a capacitor having both ends connected between a first wiring connected to the plurality of first nodes and a second wiring connected to the plurality of second nodes;
a resistor and a switch connected in series between the first wiring and the second wiring; and
a plurality of pack battery management systems (BMSs) configured to control the plurality of first relays and the plurality of second relays to be closed and, while the plurality of first relays and the plurality of second relays are closed, determine the plurality of first relays and the plurality of second relays are normal when a current flowing from the plurality of battery packs to the capacitor is detected.

9. The vehicle of claim 8, wherein:
the battery system further includes
a plurality of current sensors, each current sensor of the plurality of current sensors configured to detect a current flowing to each battery pack of the plurality of battery packs.

10. The vehicle of claim 9, wherein:
each pack BMS of the plurality of pack BMSs is configured to:
receive a current sensing signal from each respective current sensor, and when the received current sensing signal indicates a zero current, diagnose that at least one of the first relay connected to the positive electrode of the respective battery pack and second relay connected to the negative electrode of the respective battery pack is in a stuck open state.

11. The vehicle of claim 8, wherein:
the battery system further includes
a main control integrated circuit (IC) configured to discharge the capacitor by turning on the switch for a predetermined discharging period when a starting of the vehicle is off.

12. The vehicle of claim 8, further comprising:
a first main relay connected between a first input terminal of the power device and positive electrodes of the plurality of battery packs; and
a second main relay connected between a second input terminal of the power device and negative electrodes of the plurality of battery packs,
wherein the capacitor, the resistor, and the switch
are positioned between the first wiring connecting the first main relay to the positive electrodes of the plurality of battery packs and the second wiring connecting the second main relay to the negative electrodes of the plurality of battery packs.

13. The vehicle of claim 12, wherein:
the battery system is configured to
control the first main relay and the second main relay to be open during a period in which the plurality of pack BMSs determine whether the plurality of first relays and the plurality of second relays are normal.

14. The vehicle of claim 8, wherein:
the battery system
further includes a connection switch connected between the first wiring and the capacitor or between the second wiring and the capacitor.
